(19) United States
(12) Patent Application Publication
(10) Pub. No.: US 2012/0057290 A1
(43) Pub. Date: Mar. 8, 2012

(54) ALL-IN-ONE COMPUTER

(75) Inventors: CHI-KUAN SHEN, Tu-Cheng (TW); LEE-HUI KUO, Tu-Cheng (TW); CHIH-HANG CHAO, Tu-Cheng (TW)

(73) Assignee: HON HAI PRECISION INDUSTRY CO., LTD., Tu-Cheng (TW)

(21) Appl. No.: 13/076,324

(22) Filed: Mar. 30, 2011

(30) Foreign Application Priority Data
Sep. 3, 2010 (CN) 201010272086.5

(51) Int. Cl. H05K 7/20; H05K 7/00

(52) U.S. Cl. 361/679.22; 361/679.48

(57) ABSTRACT

An all-in-one computer includes a mainframe shell, a display frame, and a power supply unit (PSU). The PSU includes an outer shell, a power supply module, and a fan module. The power supply module and the fan module are accommodated in the outer shell. The power supply module includes a main body. An axis of the fan module is perpendicular to the main body.

### BACKGROUND

1. Technical Field

The present disclosure relates to an all-in-one computer.

2. Description of Related Art

All-in-one computers include a chassis, a motherboard mounted in the chassis, a display attached to a front side of the chassis, and a power supply unit (PSU) mounted in the chassis. A heat sink is mounted on a central processing unit (CPU) of the motherboard. A system fan is mounted on the heat sink for dissipating heat for the CPU and the PSU. However, the PSU generates much heat during operation, which will increase the burden on the system fan. The all-in-one computer may not maintain a temperature within a safe range.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of an all-in-one computer according to an embodiment.

FIG. 2 is an exploded view of a PSU of FIG. 1.

FIG. 3 is similar to FIG. 2, but viewed from another aspect.

FIG. 4 is an assembled view of the all-in-one computer of FIG. 1.

### DETAILED DESCRIPTION

The disclosure is illustrated by way of example and not by way of limitation. In the figures of the accompanying drawings in which like references indicate similar elements. It should be noted that references to “an” or “one” embodiment in this disclosure are not necessarily to the same embodiment, and such references mean at least one.

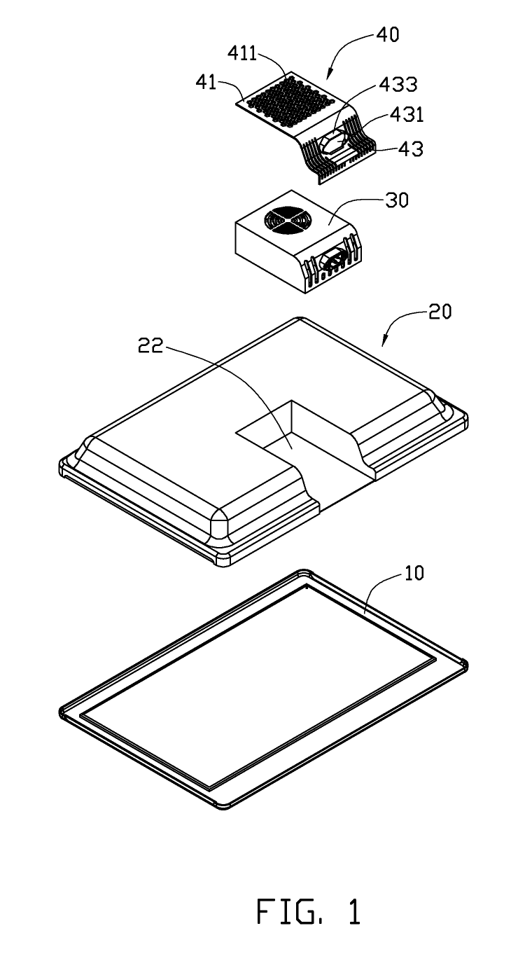

Referring to FIG. 1, an embodiment of an all-in-one computer includes a display frame 10, a mainframe shell 20, a power supply box 30, and a cover 40. A mounting cavity 22 is defined in a rear side of the mainframe shell 20. The cover 40 is configured to cover the power supply box 30 when the power supply box 30 is mounted in the mounting cavity 22. The cover 40 includes a main plate 41 and a side flange 43 extending from the main plate 41. A plurality of heat dissipation holes 411 is defined in the main plate 41. A first opening 431 is defined in the side flange 43 of the cover 40. A first enclosing piece 433 protrudes from an edge of the first opening 431.

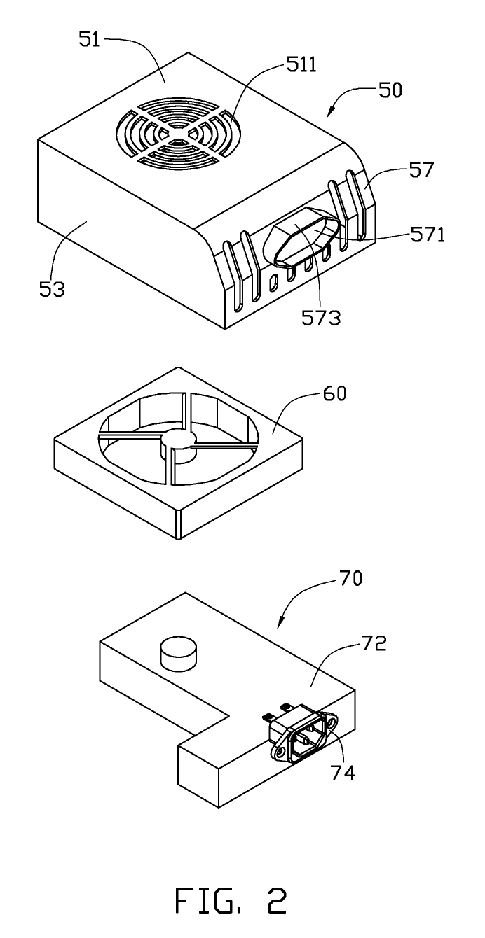

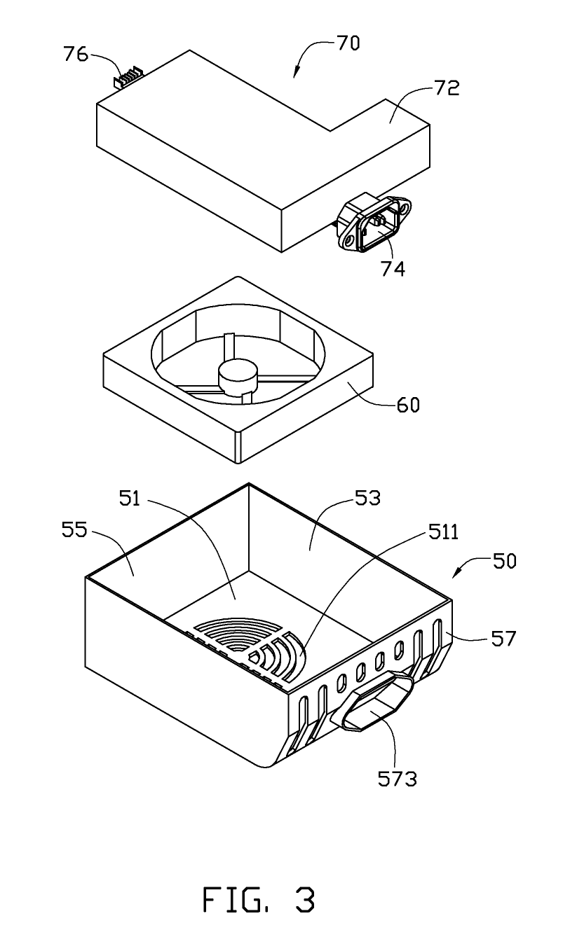

Referring to FIGS. 2 and 3, the power supply box 30 includes an outer shell 50, a fan module 60, and a power supply module 70. The outer shell 50 includes a rear panel 51, a pair of side panels 53 perpendicularly extending from opposite side edges of the rear panel 51, a top panel 55 perpendicularly extending from a top edge of the rear panel 51, and a bottom flange 57. The outer shell 50 is configured to accommodate the fan module 60 and the power supply module 70 therein. A plurality of heat dissipation apertures 511 is defined in the rear panel 51 corresponding to the fan module 60. A second opening 571 is defined in the bottom flange 57. A second enclosing piece 573 protrudes from an edge of the second opening 571.

The power supply module 70 includes a main body 72, a power plug 74 configured to connect an alternating current (AC) power supply (e.g., AC 220V), and a power connector 76 configured to output direct power rails (e.g., 3V, 5V, 12V, etc). The main body 72 is L-shaped. The power plug 74 and the power connector 76 are attached to opposite ends of the main body 72. A shape and size of the main plate 41 of the cover 40 are consistent with that of the rear panel 51 of the outer shell 50. A shape and size of the side flange 43 of the cover 40 are consistent with the bottom flange 57 of the outer shell 50.

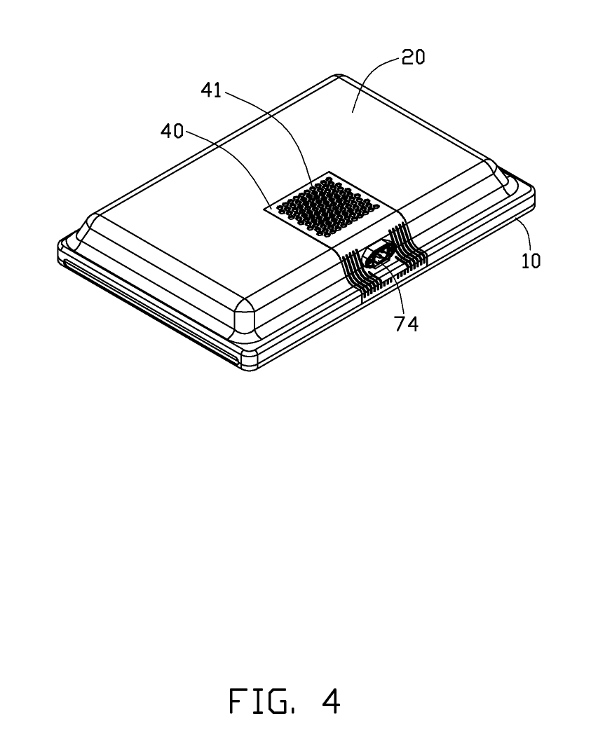

Referring to FIG. 4, in assembly, the fan module 60 is attached on the power supply module 70. Then the fan module 60 and the power supply module 70 are mounted in the outer shell 50. The power plug 74 extends through the second opening 571 of the outer shell 50. The second enclosing piece 573 encloses the power plug 74. In one embodiment, an axis of the fan module 60 is perpendicular to the power supply module 70. The heat dissipation apertures 511 of the outer shell 50 align with an airflow channel of the fan module 60.

After the power supply box 30 is assembled it is mounted in the mounting cavity 22 of the mainframe shell 20. The main plate 41 resists against the rear panel 51, and the side flange 43 resists against the bottom flange 57. The second enclosing piece 573 extends though the first opening 431 to be received in the first enclosing piece 433. The cover 40 is secured to the mainframe shell 20, and the power supply box 30 is secured in the mounting cavity 22. Then the display frame 10 is secured to a front side of the mainframe shell 20.

While the present disclosure has been illustrated by the description of preferred embodiments thereof, and while the preferred embodiments have been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. An all-in-one computer comprising:
a mainframe shell;
a display frame; and
a power supply unit (PSU) comprising an outer shell, a power supply module, and a fan module; the power supply module and the fan module being accommodated in the outer shell; and the power supply module comprises a main body, and an axis of the fan module is perpendicular to the main body.

2. The all-in-one computer of claim 1, wherein the display frame is secured to a front side of the mainframe shell, and the PSU is secured to a rear side of the mainframe shell.

3. The all-in-one computer of claim 2, wherein a mounting cavity is defined in the mainframe shell at the rear side, and the PSU is mounted in the mounting cavity.

4. The all-in-one computer of claim 1, wherein the power supply module comprises a power plug, configured to connect an alternative current power supply, and a power connector, configured to output direct current power rails.

5. The all-in-one computer of claim 4, wherein the main body is L-shaped, and the power plug and the power connector are attached to opposite ends of the main body.

6. The all-in-one computer of claim 5, wherein the outer shell includes a rear panel, a pair of side panels, perpendicularly connected to opposite side edges of the rear panel, a top panel, perpendicularly connected to a top edge of the rear panel, and a bottom flange, connected to a bottom edge of the rear panel.

7. The all-in-one computer of claim 6, wherein a plurality of heat dissipation apertures is defined in the rear panel and aligned with an airflow channel of the fan module.

8. The all-in-one computer of claim 7, wherein an opening is defined in the bottom flange, an enclosing piece protrudes from an edge of the opening, and the power plug is extended through the opening and enclosed by the enclosing piece.

9. The all-in-one computer of claim 6, further comprising a cover that lies on the PSU.

10. The all-in-one computer of claim 9, wherein the cover comprises a main plate and a side flange connected to the main plate shape and size of the main plate is consistent to that of the rear panel, and shape and size of the side flange is consistent with the bottom flange.

11. An all-in-one computer comprising:
a mainframe shell with a mounting cavity defined in a rear side thereof;
a power supply unit (PSU), mounted in the mounting cavity, comprising an outer shell, a power supply module, and a fan module; the power supply module and the fan module being accommodated in the outer shell; and the power supply module comprises a main body, and an axis of the fan module is perpendicular to the main body.

12. The all-in-one computer of claim 11, wherein the power supply module comprises a power plug configured to connect an alternative current power supply and a power connector configured to output direct current power rails.

13. The all-in-one computer of claim 12, wherein the main body is L-shaped, and the power plug and the power connector are attached to opposite ends of the main body.

14. The all-in-one computer of claim 13, wherein the outer shell includes a rear panel, a pair of side panels perpendicularly connected to opposite side edges of the rear panel, a top panel perpendicularly connected to a top edge of the rear panel, and a bottom flange connected to a bottom edge of the rear panel.

15. The all-in-one computer of claim 14, wherein a plurality of heat dissipation apertures is defined in the rear panel and aligned with an airflow channel of the fan module.

16. The all-in-one computer of claim 15, wherein an opening is defined in the bottom flange, an enclosing piece protrudes from an edge of the opening, and the power plug is extended through the opening and enclosed by the enclosing piece.

17. The all-in-one computer of claim 16, further comprising a cover that lies on the PSU.

18. The all-in-one computer of claim 17, wherein the cover comprises a main plate and a side flange connected to the main plate, shape and size of the main plate is consistent to that of the rear panel, and shape and size of the side flange is consistent with the bottom flange.

19. The all-in-one computer of claim 18, wherein the main plate abuts against the rear panel, and the side flange abuts against the bottom flange.

20. The all-in-one computer of claim 11, further comprising a display frame attached to a front side of the mainframe shell.
